(19) United States
(12) Patent Application Publication
(10) Pub. No.: US 2025/0174568 A1
(43) Pub. Date: May 29, 2025

(54) ELECTRONIC DEVICE

(71) Applicant: InnoLux Corporation, Miao-Li County (TW)

(72) Inventors: Po-Yun HSU, Miao-Li County (TW); Ju-Li Wang, Miao-Li County (TW)

(73) Assignee: InnoLux Corporation, Miao-Li County (TW)

(21) Appl. No.: 18/929,553

(22) Filed: Oct. 28, 2024

Related U.S. Application Data
(60) Provisional application No. 63/602,447, filed on Nov. 24, 2023.

(30) Foreign Application Priority Data
Jun. 21, 2024 (CN) 202410806781.7

(51) Int. Cl. H01L 23/538; H01L 21/48; H01L 23/14; H05K 1/02; H05K 1/11

(52) U.S. Cl. CPC H01L 23/5385; H01L 21/4857; H01L 23/145; H05K 1/0274; H05K 1/115; H05K 2201/10378

(57) ABSTRACT

An electronic device includes a transparent core substrate and a first buffer layer. The transparent core substrate includes a through hole, wherein the transparent core substrate includes a first transparent core layer and a second transparent core layer. The first transparent core layer includes a first sub-through hole. The second transparent core layer is bonded to the first transparent core layer, wherein the second transparent core layer includes a second sub-through hole, and the first sub-through hole overlaps the second sub-through hole to form the through hole. The first buffer layer is disposed in at least a part of the through hole.

### CROSS REFERENCE TO RELATED APPLICATION

This application claims the benefit of U.S. Provisional Application No. 63/602, 447, filed on Nov. 24, 2023. The content of the application is incorporated herein by reference.

### BACKGROUND OF THE DISCLOSURE

### 1. Field of the Disclosure

The present disclosure relates to an electronic device and particularly to an electronic device including a transparent core substrate.

### 2. Description of the Prior Art

As performance of semiconductor chips continues to improve, semiconductor packaging technology is becoming increasingly important. In a semiconductor package, a core substrate, a carrier or a circuit board is commonly used. With an increase in the number of the chips to be packaged, the density of the redistribution layer on the core substrate, the carrier or the circuit board is also increased. However, as the density of the redistribution layer increases or the number of layers within it increases, the core substrate or carrier is prone to warpage during the manufacturing processes, so that subsequent processes cannot be performed or defective products are produced.

### SUMMARY OF THE DISCLOSURE

An objective of the present disclosure is to provide an electronic device to reduce warpage during manufacturing processes and improve product yield.

An embodiment of the present disclosure provides an electronic device including a transparent core substrate and a first buffer layer. The transparent core substrate includes a through hole, wherein the transparent core substrate includes a first transparent core layer and a second transparent core layer. The first transparent core layer includes a first sub-through hole. The second transparent core layer is bonded to the first transparent core layer, wherein the second transparent core layer includes a second sub-through hole, and the first sub-through hole overlaps the second sub-through hole to form the through hole. The first buffer layer is disposed in at least a part of the through hole.

An embodiment of the present disclosure provides a manufacturing method of an electronic device. First, a transparent core substrate and a first buffer layer are formed, wherein the transparent core substrate includes a through hole, the first buffer layer is disposed in at least a part of the through hole. The transparent core substrate includes a first transparent core layer and a second transparent core layer. The first transparent core layer includes a first sub-through hole. The second transparent core layer is bonded to the first transparent core layer, wherein the second transparent core layer includes a second sub-through hole, and the first sub-through hole overlaps the second sub-through hole to form the through hole. Then, a first redistribution layer is formed on a surface of the first transparent core layer away from the second transparent core layer.

In the electronic device and the manufacturing method thereof of the present disclosure, stacking plural transparent core layers may improve the stiffness of the transparent core substrate and reduce the difference between the maximum aperture and the minimum aperture of the through hole. Therefore, the transparent core substrate may be used as a core substrate to mitigate the warpage during forming the redistribution layer, thereby improving the yield of manufacturing the electronic device.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 5 schematically illustrate cross-sectional views at different steps of a manufacturing method of an electronic device according to a first embodiment of the present disclosure.

FIG. 6 schematically illustrates a cross-sectional view of an electronic device according to a first variant embodiment of the first embodiment of the present disclosure.

FIG. 7 schematically illustrates a cross-sectional view of an electronic device according to a second variant embodiment of the first embodiment of the present disclosure.

FIG. 8 schematically illustrates a cross-sectional view of an electronic device according to a third variant embodiment of the first embodiment of the present disclosure.

FIG. 9 schematically illustrates a cross-sectional view of an electronic device according to a fourth variant embodiment of the first embodiment of the present disclosure.

FIG. 10 schematically illustrates a cross-sectional view of an electronic device according to a second embodiment of the present disclosure.

FIG. 11 to FIG. 16 schematically illustrate cross-sectional views at different steps of a manufacturing method of an electronic device according to a third embodiment of the present disclosure.

FIG. 17 schematically illustrates a top view of the grooves according to some embodiments of the present disclosure.

FIG. 18 schematically illustrates a cross-sectional view of an electronic device according to a fourth embodiment of the present disclosure.

FIG. 19 schematically illustrates a cross-sectional view of an electronic device according to a fifth embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the elements in the drawings are just illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. It does not mean that the element has any previous ordinal numbers, nor does it represent the order of a certain element and another element, or the sequence in a manufacturing method. These ordinal numbers are just used to make a claimed element with a certain name be clearly distinguishable from another claimed element with the same name.

In addition, when one element or layer is “connected to” another element or layer, it may be understood that the element or layer is directly connected to the another element or layer, and alternatively, they are physically or electrically (indirectly) connected to each other through another intervening element or layer. On the contrary, when the element or layer is “directly connected to” the another element or layer, it may be understood that the element or layer and the another element or layer are physically or electrically connected to each other without through another intervening element or layer. The term “connected” may include means of “direct contact” or “indirect contact”. Also, the term “electrically connected” or “coupled” includes means of direct or indirect electrical connection.

In the present disclosure, when one element is “disposed” on another element, it does not limit the process steps or the sequence of forming the element and forming the another element.

As disclosed herein, the terms “approximately”, “essentially”, “about”, or “substantially” generally mean within 208, 10%, 5%, 3%, 2%, 1%, or 0.5% of the reported numerical value or range. The quantity disclosed herein is an approximate quantity, that is, without a specific description of “approximately”, “essentially”, “about”, or “substantially”, the quantity may still include the meaning of “approximately”, “essentially”, “about”, or “substantially”.

The term “range from a value A to a value B” is interpreted as including the value A and the value B or at least one of the value A or the value B, and including other values between the value A and value B.

In the present disclosure, the depth, thickness, length, width, and diameter may be measured by using an optical microscope (OM), a scanning electron microscope (SEM) or other suitable methods, but not limited thereto.

In the present disclosure, to determine “roughness” may be defined by a height difference of 0.15 micrometers (μm) to 1 μm between a peak and a valley of a wave observed from uneven surface by using SEM. The measurement of “roughness” may include using SEM, transmission electron microscope (TEM), etc., to observe the uneven surface in an appropriate magnification and taking a sample with a unit length (e.g., 10 μm) to compare the uneven degrees to obtain the roughness range. The term “appropriate magnification” mentioned herein means that a roughness (Rz) or an average roughness (Ra) of at least a surface having at least ten ups and downs is able to be viewed in this magnification.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

The electronic device of the present disclosure may, for example, a semiconductor device and may be adapted to any one of devices. The electronic device may include a display device, a lighting device, a sensing device, an antenna device, a touch device, a tiled device, a package device or other suitable electronic device, but not limited thereto. The electronic device may, for example, be a bendable, stretchable, foldable, rollable and/or flexible electronic device. The display device may, for example, be applied to a laptop, a public display, a tiled display, a car display, a touch display, a television, a monitor, a smartphone, a tablet, a light source module, an illumination equipment, a military equipment or an electronic device applied to the above-mentioned product, but not limited thereto. The sensing device may, for example, be a sensing device used for detecting variation in capacitances, light, heat, or ultrasound, but not limited thereto. The sensing device may, for example, include a biosensor, a touch sensor, a fingerprint sensor, other suitable sensors, or any combination of sensors mentioned above. The display device may, for example, include liquid crystal molecules, light emitting diodes, a fluorescent material, a phosphor material, other suitable display medium, or any combination of the above-mentioned display medium, but not limited thereto. The light emitting diode may, for example, include an organic light emitting diode (OLED), a mini light emitting diode (mini LED), a micro light emitting diode (micro LED), a quantum dot light emitting diode (e.g., QLED or QDLED), other suitable materials, or any combination of the above-mentioned material, but not limited thereto. The antenna device may, for example, be a liquid crystal antenna, a varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems such as a driving system, a control system, a light source system, a shelf system, etc. The electronic device may include electronic units, in which the electronic units may include a passive component and an active component, and for example include a capacitor, a resistor, an inductor, a diode, a transistor, a sensor, etc. It is noted that the electronic device of the present disclosure may be any combination of the above-mentioned devices, but not limited thereto. It is noted that the manufacturing method of the electronic device in the present disclosure may be applied to, for example, a wafer-level package (WLP) process or a panel-level package (PLP) process, which includes, but is not limited to, a chip-first process or a chip-last process. The electronic device of the present disclosure may include, for example, a power module, a semiconductor package device, a display device, a lighting device, a backlight device, an antenna device, a sensing device, or a tiled device. The electronic device may include a system on a chip (SoC), a system in a package (SiP), an antenna in package (AiP) or any combination of the above devices, but not limited thereto.

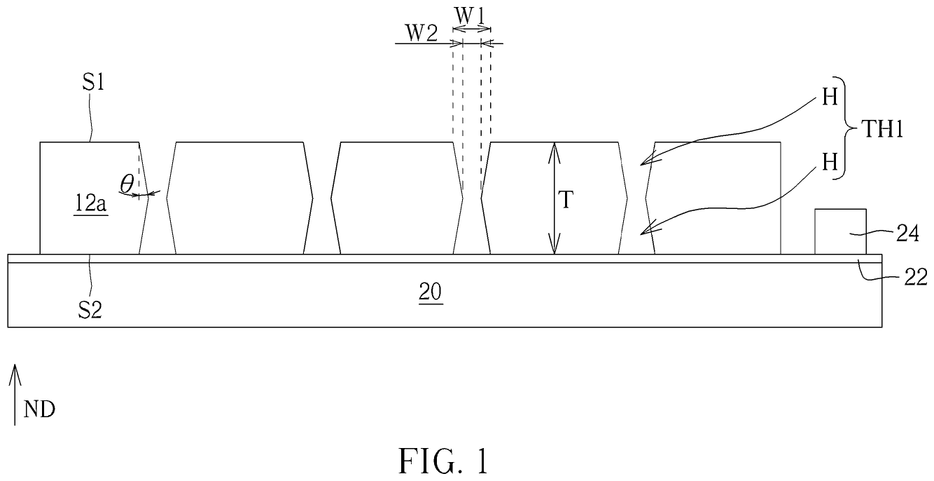

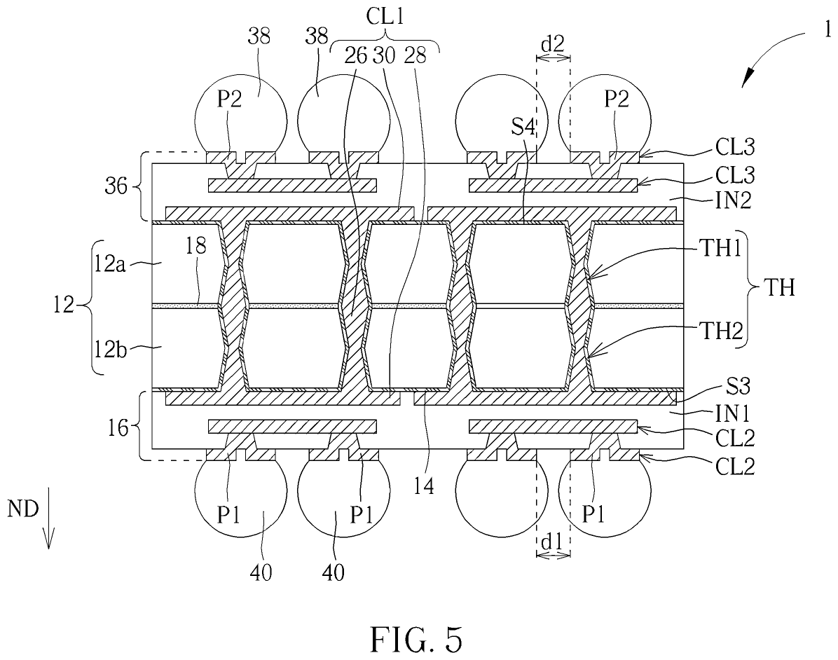

FIG. 1 to FIG. 5 schematically illustrate cross-sectional views at different steps of a manufacturing method of an electronic device according to a first embodiment of the present disclosure, wherein FIG. 5 is a schematic cross-sectional view of the electronic device according to the first embodiment of the present disclosure. The manufacturing method of the electronic device of the present disclosure may include following steps, and the manufacturing method of the present disclosure is not limited to the following steps. Another step may be performed before, after or during any of the steps. As shown in FIG. 1 to FIG. 5, the manufacturing method of the electronic device 1 may include forming a transparent core substrate 12 and a buffer layer 14 and forming a redistribution layer 16, wherein the transparent core substrate 12 includes at least one through hole TH, and the buffer layer 14 is disposed in at least a part of the through hole TH, in detail, the buffer layer covers at least a portion of a sidewall of the through hole TH. The transparent core substrate 12 includes a transparent core layer 12a and a transparent core layer 12b, wherein the transparent core layer 12a includes at least one sub-through hole TH1, and the transparent core layer 12b includes at least one sub-through hole TH2. The transparent core layer 12b may be bonded to the transparent core layer 12a, such that the sub-through hole TH1 overlaps the sub-through hole TH2 to form the through hole TH. The redistribution layer 16 is formed on a surface of the transparent core layer 12a away from the transparent core layer 12b. The numbers of the sub-through hole TH1, the sub-through hole TH2, and the through hole are plural as an example in the following content, but not limited thereto. In some of the embodiments, in a cross-sectional view of the electronic device, a profile of the sub-through hole TH1 and a profile of the sub-through hole TH2 include hourglass shape, trapezoid, oval, rectangle, a combination of above or any other suitable shape. It should be noted that, by using the transparent core substrate 12 as a core substrate, warpage may be reduced during forming the redistribution layer 16, thereby improving the yield of manufacturing the electronic device 1. For example, the transparent core layer 12a and the transparent core layer 12b may include a glass substrate, a silicon-containing transparent material, an optical layer, an acrylic plate or a combination thereof or other transparent materials, so as to have a certain stiffness and insulating property. In other words, a stiffness of the transparent core substrate 12 is greater than a stiffness of the redistribution layer 16, for example, the stiffness of the transparent core substrate 12 is greater than the stiffness of an insulating layer of the redistribution layer 16. Accordingly, when the transparent core substrate 12 is used to carry the redistribution layer 16, the warpage may be mitigated, but not limited thereto. Alternatively, dielectric loss of the transparent core substrate 12 is less than dielectric loss of the insulating layer of the redistribution layer 16, so that when the transparent core substrate 12 is used to carry the redistribution layer 16, the electrical characteristics of the electronic device 1 may be improved, but not limited thereto.

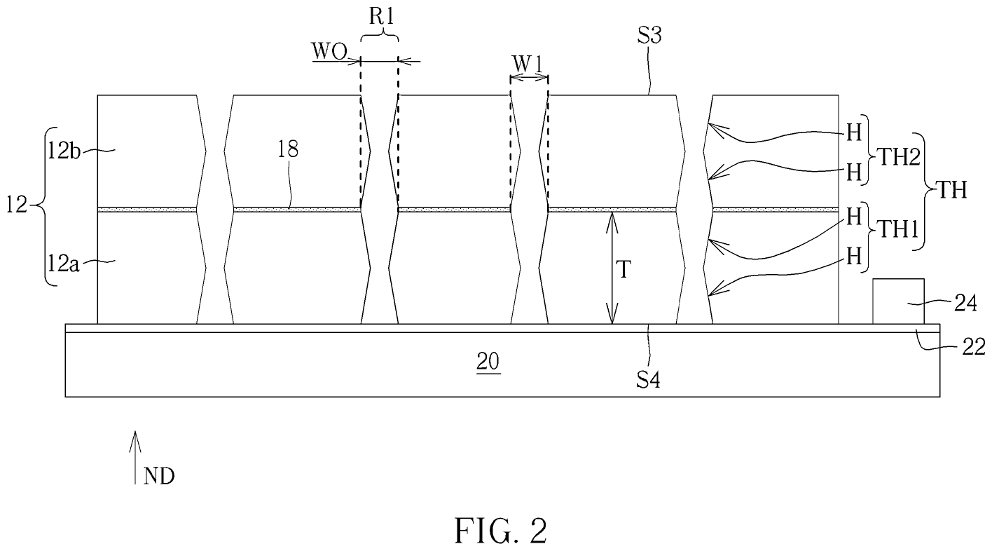

Specifically, the manufacturing method of the electronic device 1 in this embodiment is described in detail below in combination with FIG. 1 to FIG. 5. As shown in FIG. 1 and FIG. 2, the step of forming the transparent core substrate 12 and the buffer layer 14 may include performing a step of forming the transparent core substrate 12 and a step of forming the buffer layer 14 in sequence. The step of forming the transparent core substrate 12 in this embodiment may include forming the transparent core layer 12a and the transparent core layer 12b separately and bonding the transparent core layer 12b to the transparent core layer 12a through an interposer 18 to form the transparent core substrate 12.

In detail, as shown in FIG. 1, the transparent core layer 12a and the transparent core layer 12b may be first formed separately. In FIG. 1, the method of forming the transparent core layer 12a may include providing a transparent substrate and then performing a patterning process on two surfaces of the transparent substrate opposite to each other to form the transparent core layer 12a having the sub-through holes TH1, wherein the sub-through holes TH1 penetrates through the transparent core layer 12a. The transparent substrate may be, for example, glass. In this case, the patterning process may, for example, include performing a modification process on a part of the transparent substrate where the sub-through holes TH1 are to be formed and then performing an etching process, a photolithographic and etching process, or other suitable processes on the modified transparent substrate. The modification process may, for example, include irradiating a laser, and the etching process may, for example, include a wet etching process using an etchant, so that the etchant may have a significant etching selectivity to different parts of the transparent substrate, thereby forming the sub-through holes TH1. In other words, the transparent substrate may allow laser light to penetrate through, but not limited thereto. In some embodiments, the sub-through holes TH1 may be formed by etching both sides of the transparent substrate sequentially or simultaneously, but not limited thereto. The “modification” mentioned in the present disclosure is to adjust bonding strengths of local areas of the transparent core layer 12a and the transparent core layer 12b by laser or other suitable processes, or to weaken structural strength of the local areas. According to some embodiments, the etchant may include acidic liquid or alkaline liquid, wherein the acidic etchant includes hydrofluoric acid, and the alkaline etchant includes sodium hydroxide, but not limited thereto. According to some embodiments, an average roughness of the sub-through hole TH1 or the groove 66a may range from 0.1 μm to 1 μm, so as to improve the bonding strength of a layer formed subsequently with the transparent core layer 12a, but not limited thereto.

It should be noted that the sub-through holes TH1 may be formed by etching from a single surface of the transparent core layer 12a or etching from a surface S1 and a surface S2 of the transparent core layer 12a opposite to each other. For example, when the sub-through holes TH1 are formed by etching from the surface S1 and the surface S2 of the transparent core layer 12a opposite to each other, each of the sub-through holes TH1 may be formed by connecting two holes H, and the holes H may be etched from the surface S1 and the surface S2, respectively. By adjusting parameters of the modification process and the etching process, the sub-through holes TH1 may have a more uniform aperture, that is, the difference between the maximum aperture W1 and the minimum aperture W2 of one of the sub-through holes TH1 may be reduced. For example, a ratio of the maximum aperture W1 to the minimum aperture W2 (i.e., maximum aperture W1/minimum aperture W2) may range from 1.01 to 2 or from 1.1 to 1.6. In the embodiment of FIG. 1, the aperture of one of the holes H adjacent to the surface S1 may decrease as the distance between the aperture and the surface S1 increases. Similarly, the aperture of one of the holes H adjacent to the surface S2 may decrease as the distance from the aperture to the surface S2, but not limited thereto. For example, an acute angle θ between a sidewall of the hole H adjacent to the surface S1 and a normal direction ND of the surface S1 may be less than or equal to 20 degrees. Similarly, an acute angle between a sidewall of the hole H adjacent to the surface S2 and the normal direction ND may be less than or equal to 20 degrees. The angle θ of the hole H adjacent to the surface S1 and the angle of the hole H adjacent to the surface S2 may be the same as or different from each other. In some embodiments, each of the holes H may have substantially uniform aperture as the distance between the aperture and the surface S1 or between the aperture and the surface S2 changes. In some embodiments, in a cross-sectional view, one of the sub-through holes TH1 may be hourglass-shaped, rectangular, trapezoidal, inverted trapezoidal or other suitable shapes.

As shown in FIG. 1, a thickness T of the transparent core layer 12a of this embodiment, that is, a depth of one of the sub-through holes TH1, may be, for example, greater than or equal to 200 μm and less than or equal to 500 μm. In this case, the maximum aperture W1 of the sub-through hole TH1 may be, for example, greater than or equal to 30 μm and less than or equal to 60 μm. The minimum aperture W2 of the sub-through hole TH1 may be, for example, greater than or equal to 15 μm and less than or equal to 30 μm. The size of the sub-through hole TH1 of the present disclosure is not limited to the content mentioned above.

In some embodiments, since the step of forming the second transparent core layer 12b may be the same as the step of forming the transparent core layer 12a, one of the sub-through holes TH2 may be the same as or similar to one of the sub-through holes TH1 and may be formed by connecting two holes H. Accordingly, maximum aperture and minimum aperture of the sub-through hole TH2 and a thickness of the transparent core layer 12b may be the same as or similar to the maximum aperture W1 and the minimum aperture W2 of the sub-through hole TH1 and the thickness T of the transparent core layer 12a, respectively. According to some embodiments, a percentage (%) of an absolute value of a difference between the maximum aperture of the sub-through hole TH2 and the maximum aperture W1 of the sub-through hole TH1 to the maximum aperture W1 of the sub-through hole TH1 may less than or equal to 15%. A percentage of an absolute value of a difference between the minimum aperture of the sub-through hole TH2 and the minimum aperture W2 of the sub-through hole TH1 to the minimum aperture W2 of the sub-through hole TH1 may less than or equal to 15%. A percentage of an absolute value of a difference between the thickness of the transparent core layer 12b and the thickness T of the transparent core layer 12a to the thickness T of the transparent core layer 12a may be less than or equal to 15%. Through the configuration mentioned above, stress imbalance may be reduced, or stability in the processes may be improved, but not limited thereto.

As shown in FIG. 1, after forming the transparent core layer 12a and the transparent core layer 12b, the transparent core layer 12a (or the transparent core layer 12b) may be optionally disposed on a carrier 20. In some embodiments, before disposing the transparent core layer 12a, a release layer 22 may be optionally formed on the carrier 20 to facilitate separation of the transparent core substrate 12 formed subsequently from the carrier 20.

As shown in FIG. 2, a lamination process may be then performed, and the transparent core layer 12b is bonded to the transparent core layer 12a through the interposer 18 to form the transparent core substrate 12, wherein one of the sub-through holes TH1 may overlap one of the sub-through holes TH2 to form one of the through holes TH, and the interposer 18 may be disposed between the transparent core layer 12a and the transparent core layer 12b. It is noted that the stack of the transparent core layer 12b and the transparent core layer 12a may reduce the difference between the maximum aperture and the minimum aperture of the through hole TH while the stiffness of the transparent core substrate 12 is improved. In some embodiments, the number of the transparent core layers used for forming the transparent core substrate 12 may not be limited to two, but may be three or more. In this case, the aperture uniformity of each of the sub-through holes of each transparent core layer may be improved by reducing the thickness of each transparent core layer, but not limited thereto. The transparent core substrate 12 may, for example, allow laser light to penetrate through.

In one embodiment, the interposer 18 may be formed on a surface of the transparent core layer 12a or the transparent core layer 12b before the transparent core layer 12b is bonded to the transparent core layer 12a. The lamination process may, for example, include an annealing process, wherein the temperature of the annealing process may, for example, be greater than or equal to 150° C. and less than or equal to 600° C. In this case, a tolerated temperature of the interposer 18 is greater than or equal to 150° C. In some embodiments, the lamination process may optionally include a pressing process for the transparent core layer 12b and the transparent core layer 12a, but is not limited thereto.

The interposer 18 may, for example, include an inorganic material or an organic material. The inorganic material may include a material that is homogeneous with glass, such that after the annealing process, the material of the interposer 18 may be the same as or similar to the material of the transparent core layer 12a and the transparent core layer 12b. The inorganic material may include, for example, silica, tetraethoxysilane (TEOS), a material containing silicon, a glass-like material, or other suitable material. In this case, the thickness of the interposer 18 may be, for example, greater than or equal to 1 nanometer (nm) and less than or equal to 20 nm (i.e., 1 nm≤the thickness of the interposer 18≤20 nm). The organic material may include a material that is heterogeneous to the glass, and the organic material includes, for example, an adhesive or other suitable material. In this case, after the annealing process, the material of the interposer 18 may be different from the material of the transparent core layer 12a and the transparent core layer 12b, and the thickness of the interposer 18 may be, for example, greater than or equal to 1 μm and less than or equal to 10 μm (i.e., 1 μm≤the thickness of the interposer 18≤10 μm). The interposer 18 may, for example, be adhesive and transparent. It should be noted that “transparent” herein may refer to, but not limited to, an element having a light transmittance of greater than or equal to 90%. A refractive index of the interposer 18 may be different from a refractive index of the transparent core layer 12a. For example, the refractive index of the interposer 18 is less than the refractive index of the transparent core layer 12a.

In some embodiments, the interposer 18 may have a dissipation factor (Df), and the dissipation factor is greater than or equal to 0.001 and less than or equal to 0.01 (i.e., 0.001≤Df≤0.01) at an operating frequency greater than or equal to 10 MHz, so that the influence of the interposer 18 on signal transmission may be reduced.

In addition, as shown in FIG. 1 and FIG. 2, before the transparent core layer 12b is bonded to the transparent core layer 12a, an alignment mark 24 may be disposed or formed on the carrier 20 to facilitate alignment of each of the sub-through holes TH2 of the transparent core layer 12b with the corresponding sub-through hole TH1 of the transparent core layer 12a. According to some embodiments, when the manufacturing process of the electronic device 1 uses the carrier 20, and the stiffness of the carrier 20 is greater than that of the transparent core layer 12a or the transparent core layer 12b, the carrier 20 may resist deformation, which improves the reliability of the electronic device 1. The carrier 20 may include a wafer, a steel plate, a glass substrate, or any substrate material suitable for carrying objects. According to some embodiments, in the normal direction ND, the thickness of the carrier 20 may be greater than that of at least one of the transparent core layer 12a or the transparent core layer 12b. In a direction perpendicular to the normal direction ND, a width of the carrier 20 is greater than that of at least one of the transparent core layer 12a or the transparent core layer 12b. The above configuration may help to improve the stability of the electronic device 1 during the manufacturing processes, but not limited thereto.

It should be noted that one of the sub-through holes TH1 and the corresponding sub-through hole TH2 may have an overlapping area R1, and the overlapping area R1 includes an overlapping width WO. The overlapping width WO may be greater than or equal to 0.5 times the maximum aperture W1 of the sub-through hole TH1 and less than or equal to the maximum aperture W1 of the sub-through hole TH1 (i.e., 0.5 times the maximum aperture W1≤overlapping width WO≤maximum aperture W1). The overlapping area R1 may refer to a region of a part of the sub-through hole TH1 closest to the sub-through hole TH2 overlapping a part of the sub-through hole TH2 closest to the sub-through hole TH1 in the normal direction ND of the surface S3 of the transparent core substrate 12. For example, the part of the sub-through hole TH1 closest to the sub-through hole TH2 may be a part of the hole H of the sub-through hole TH1 adjacent to the sub-through hole TH2 having the maximum aperture W1, and the part of the sub-through hole TH2 closest to the sub-through hole TH1 is a part of the hole H of the sub-through hole TH2 adjacent to the sub-through hole TH1 having the maximum aperture W1, but not limited thereto. In FIG. 2, the overlapping width WO may be the same as the maximum aperture W1, but not limited thereto. Through designing the overlapping width WO of the sub-through hole TH1 and the sub-through hole TH2 to be within the above range, it is helpful to reduce the possibility of disconnection of the conductive vias 26 subsequently formed in the through holes TH, but the present disclosure is not limited thereto.

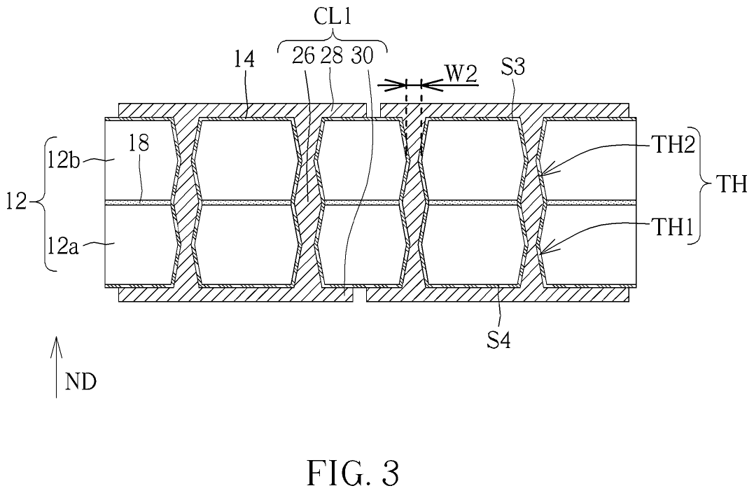

As shown in FIG. 3, after the transparent core substrate 12 is formed, the carrier 20 may be removed through the release layer 22, and the buffer layer 14 is then formed on the transparent core substrate 12, so that the buffer layer 14 may be disposed in at least a part of each of the through holes TH. For example, the buffer layer 14 may be formed in the sub-through holes TH1 and the sub-through holes TH2 and on the surface S3 and the surface S4 of the transparent core substrate 12. The method of forming the buffer layer 14 may include a deposition process or other suitable processes. The deposition process may include, for example, coating, evaporation, atomic layer deposition or other physical deposition processes or chemical deposition processes. The material of the buffer layer 14 may include, for example, an organic material, such as polyimide (PI), poly-p-xylylene (parylene), benzocyclobutene (BCB), epoxy, polycarbonate (PC), polyethylene terephthalate (PET), polyethylene naphthalate (PEN), polymers, or an inorganic material.

In the embodiment of FIG. 3, the buffer layer 14 may cover the sidewalls of the through holes TH and the surface of the transparent core substrate 12 outside the through holes TH, but not limited thereto. The thickness of the buffer layer 14 may be, for example, greater than or equal to 0.01 μm and less than or equal to 10 μm (i.e., 0.01 μm≤thickness of the buffer layer 14≤10 μm). For example, as the thickness of the buffer layer 14 is gradually thinner from the surface of the transparent core substrate 12 outside the through holes TH to another surface away from the surface, a part of the buffer layer 14 covering a part of one of the through holes TH with the minimum aperture W2 may have a minimum thickness, but not limited thereto. A ratio of the thickness of the buffer layer 14 to the aperture of one of the sub-through holes TH1 may be, for example, greater than or equal to 0.02 and less than or equal to 0.2 (i.e., 0.02≤ratio of the thickness of the buffer layer 14 to the aperture of the sub-through hole TH1≤0.2). For example, the ratio of the minimum thickness of the buffer layer 14 at the minimum aperture W2 to the minimum aperture W2 of the sub-through hole TH1 may be greater than or equal to 0.02 and less than or equal to 0.2. The toughness of the buffer layer 14 may be greater than or equal to 0.1 KJ/m² and less than or equal to 100 KJ/m² (i.e., 0.1 kJ/m²≤toughness of the buffer layer 14≤100 KJ/m²). In the present disclosure, the toughness of a layer may be obtained by integrating an area under a stress-strain curve, and the stress-strain curve may be obtained by performing a tensile test on the layer using a universal testing machine (UTM).

As shown in FIG. 3, after forming the buffer layer 14, a plurality of conductive vias 26 may be formed in the through holes TH, respectively. In this embodiment, forming the conductive vias 26 may further include forming traces 28 and traces 30 on the surface S3 and the surface S4 of the transparent core substrate 12 outside the through holes TH, respectively. In other words, the conductive vias 26, the traces 28, and the traces 30 may be formed of the same conductive layer CL1 or include the same conductive material, but not limited thereto. The step of forming the conductive layer CL1 may, for example, include a metallization process, wherein the metallization process may, for example, include evaporation, sputtering, electroplating, chemical plating, deposition, or other suitable processes. It is noted that since the difference between the maximum aperture and the minimum aperture of the through hole TH may be decreased, the difference between the maximum diameter and the minimum diameter of one of the conductive vias 26 formed in the corresponding through hole TH may be reduced, thereby reducing cracks or disconnections of the conductive vias 26 while the conductive vias 26 are subjected to stress or external force. According to some embodiments, the conductive layer CL1 may include a single layer or a composite layer. For example, when the conductive layer CL1 is the composite layer, it may include a first sub-layer and a second sub-layer, and the first sub-layer is provided between the second sub-layer and the transparent core substrate 12. The first sub-layer may be, for example, a seed layer, which enhance bonding force between the second sub-layer and the transparent core substrate 12 or enhance conductivity of the conductive layer CL1, but not limited thereto.

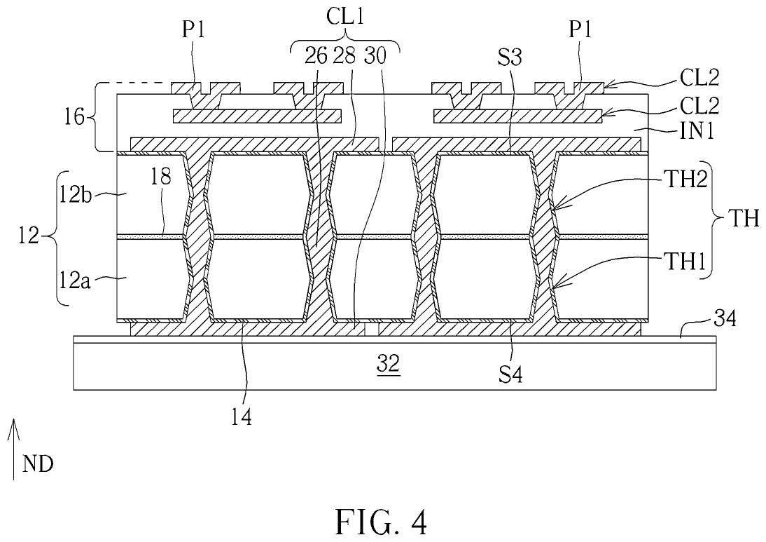

As shown in FIG. 4, after forming the conductive via 26, the transparent core substrate 12 may be optionally disposed on another carrier 32, so that the surface S3 (or the surface S4) of the transparent core substrate 12 faces upward, and then a redistribution layer 16 is formed on the surface S3 (or the surface S4) of the transparent core substrate 12. In some embodiments, a release layer 34 may be optionally formed on the carrier 20 to facilitate separation of the transparent core substrate 12 from the carrier 32 in the subsequent process.

In this embodiment, the redistribution layer 16 is formed after the transparent core substrate 12 and the buffer layer 14 are formed, but not limited thereto. The step of forming the redistribution layer 16 may include providing a stack of at least one insulating layer and at least one conductive layer. For example, the step of forming the redistribution layer 16 includes processes, such as photolithography, etching, surface treatment, laser, electroplating, etc. The surface treatment process may include roughening a surface of the insulating layer or a surface of the conductive layer to enhance adhesion. The redistribution layer 16 may be electrically connected to at least one chip or electronic unit through bonding pads or other bonding elements. The redistribution layer 16 may include at least one conductive layer and at least one insulating layer, may redistribute lines and/or further increase fan-out area for lines, or may electrically connect different electronic units to each other. Alternatively, the redistribution layer may be a substrate or structure used as electrical interface redistribution between one connection and another connection. The purpose of the redistribution layer is to expand the connection to have wider spaces of lines or to reroute the connection to another connection with different space from that of the connection. For example, the insulating layer may include polyimide (PI), photosensitive polyimide (PSPI), Ajinomoto build-up film (ABF), silicon oxide (SiOx), silicon nitride (SiNx), silicon oxide nitride (SiOxNy) or other suitable dielectric materials. The conductive layer may include a conductive material, such as copper (Cu), titanium (Ti), aluminum (Al), molybdenum (Mo), nickel (Ni), ruthenium (Ru), tantalum (Ta), tungsten (W), nitride, carbide or other conductive materials or any combination thereof, but not limited thereto. According to some embodiments, the redistribution layer 16 may include an electronic unit, that is, the electronic unit may be embedded or formed in the redistribution layer 16.

In the embodiment of FIG. 4, the conductive layer of the redistribution layer 16 may include a part of the conductive layer CL1 and at least one conductive layer CL2, and FIG. 4 illustrates an insulating layer IN1 for representing a combination of plural insulating layers, but the present disclosure is not limited thereto. Each insulating layer may have at least one through hole, such that the conductive layer CL1 has an electrical connection with the conductive layer CL2 in a stacking direction. Although FIG. 4 shows that there is no connection between the conductive layer CL1 and the conductive layer CL2, the conductive layer CL1 may still be electrically connected to the conductive layer CL2 at other positions, so that the redistribution layer 16 is able to achieve a vertical electrical connection. In addition, the conductive layer CL2 farthest from the transparent core substrate 12 may include a plurality of bonding pads P1 for being bonded to an electronic unit, a circuit board, or other suitable components. In some embodiments, the redistribution layer 16 may not include the conductive layer CL1 when the conductive layer CLI is not disposed outside the through hole TH of the transparent core substrate 12. In some embodiments, the thickness of the single insulating layer of the redistribution layer 16 may be, for example, greater than or equal to 5 um and less than or equal to 25 μm (i.e., 5 μm≤the thickness of the insulating layer≤25 μm), and the thickness of the single insulating layer of the redistribution layer 16 may be greater than the thickness of the buffer layer 14. According to some embodiments, the conductive layer CL2 may include a single layer or a composite layer. For example, when the conductive layer CL2 is the composite layer, the conductive layer CL2 may include a first sub-layer and a second sub-layer, and the first sub-layer is disposed between the second sub-layer and the insulating layer IN1. The first sub-layer may, for example, be a seed layer, which may enhance bonding force between the second sub-layer and the insulating layer IN1 or enhance conductivity of the redistribution layer 16, but not limited thereto.

As shown in FIG. 5, after forming the redistribution layer 16, the carrier 32 may be removed, and the transparent core substrate 12 may be turned upside down, so that the surface S3 of the transparent core substrate 12 formed with the redistribution layer 16 is placed downward on another carrier (not shown). Then, another redistribution layer 36 is formed on the surface S4 of the transparent core substrate 12 away from the transparent core layer 12b. The method of forming the redistribution layer 36 may be the same as or similar to the method of forming the redistribution layer 16, and it will not be described in detail herein.

The redistribution layer 36 may also include at least one insulating layer and at least one conductive layer, and the number of the insulating layer and the number of the conductive layer may be respectively adjusted to be the same as or different from the number of the insulating layer and the number of conductive layer of the redistribution layer 16 according to the requirements. In the redistribution layer 36 of FIG. 5, the conductive layer may include a portion of the conductive layer CL1 and at least one conductive layer CL3, and FIG. 5 illustrates a single insulating layer IN2 for representing a combination of multiple insulating layers, but the present disclosure is not limited thereto. Each insulating layer may have at least one through hole, so that the conductive layer CL1 and the conductive layer CL3 are electrically connected to each other in the stacking direction. Although FIG. 5 shows that there is no connection between the conductive layer CL1 and the conductive layer CL3, the conductive layer CL1 may still be electrically connected to the conductive layer CL3 at other positions, so that the redistribution layer 36 achieves the purpose of vertical electrical connection. In some embodiments, the thickness of the single insulating layer of the redistribution layer 16 and/or the redistribution layer 36 may be greater than the thickness of the buffer layer 14. In FIG. 5, the conductive layer CL2 of the redistribution layer 36 farthest from the transparent core substrate 12 may also include a plurality of bonding pads P2 for being bonded to an electronic unit, a circuit board or other suitable components. In some embodiments, when the conductive layer CL1 is not disposed outside the through holes TH of the transparent core substrate 12, the redistribution layer 36 may not include the conductive layer CL1.

It should be noted that in the step of forming the redistribution layer 16 and/or in the step of forming the redistribution layer 36, the densities of the conductive layers respectively on the surface S3 and the surface S4 of the transparent core substrate 12 may be different, so that the transparent core substrate 12 may be subjected to uneven stresses. Since the transparent core substrate 12 of this embodiment may for example include glass, the transparent core substrate 12 may have certain stiffness. Accordingly, warpage may be reduced during the step of forming the redistribution layer 16 and/or during the step of forming the redistribution layer 36, so as to improve the yield of manufacturing the electronic device 1.

After the redistribution layer 36 is formed, a plurality of bonding pads 38 may be respectively formed on the bonding pads P2 of the redistribution layer 36. Subsequently, the carrier is removed, and a plurality of bonding pads 40 are respectively formed on the bonding pads P1 of the redistribution layer 16, thereby forming the electronic device 1. The bonding pads 38 and the bonding pads 40 may include, for example, solder balls, nickel, gold, copper, gallium or other suitable conductive materials, and the bonding pads 38 may be electrically connected to the corresponding bonding pads 40 through the redistribution layer 36, the conductive vias 26 and the redistribution layer 16. According to some embodiments, one of the bonding pad 40 may include a part of the corresponding bonding pad P1 to achieve hybrid bonding. As shown in FIG. 5, an upper side of the electronic device 1 may be bonded to other suitable elements through the bonding pads 38, and a lower side of the electronic device 1 may be bonded to other suitable elements through the bonding pads 40, so that the electronic device 1 may be used as a redistribution substrate, for example, used to carry at least one electronic unit or other elements and electrically connect them to other circuits, or to electrically connect multiple electronic units to each other. According to some embodiments, a distance d1 between adjacent two of the bonding pads P1 is different from a distance d2 between adjacent two of the bonding pads P2 in a direction perpendicular to the normal direction ND.

As shown in FIG. 5, the electronic device 1 may at least include the transparent core substrate 12 and the buffer layer 14, wherein the transparent core substrate 12 may include the through holes TH and include the transparent core layer 12a including the sub-through holes TH1 and the transparent core layer 12b including the sub-through holes TH2. The transparent core layer 12b may be bonded to the transparent core layer 12a, and the sub-through holes TH1 may respectively overlap the sub-through holes TH2 to form the through holes TH. The buffer layer 14 may be provided in at least a part of each of the through holes TH. By stacking the transparent core layer 12a with the transparent core layer 12b, the transparent core substrate 12 of the electronic device 1 may have the through holes TH with certain uniformity of apertures as the transparent core substrate 12 has certain stiffness. According to some embodiments, the buffer layer 14 may be disposed on the surface of the transparent core substrate 12 and extend into the at least a part of the through holes TH.

In the embodiment of FIG. 5, the conductive vias 26 may be provided in the through holes TH of the transparent core substrate 12, and the redistribution layer 16 and the redistribution layer 36 may be provided on the surface S3 and the surface S4, respectively, such that the transparent core substrate 12 may be provided between the redistribution layer 16 and the redistribution layer 36, and the redistribution layer 16 may be electrically connected to the redistribution layer 36 through the conductive via 26. It is noted that, when the density of bonding pads of the redistribution layer 16 and/or the redistribution layer 36 increases, or the line density of the conductive layers of the redistribution layer 16 is different from that of the redistribution layer 36, the transparent core substrate 12 located between the redistribution layer 16 and the redistribution layer 36 may be subjected to uneven stress. Particularly, when computing power of the electronic unit to be bonded increases, the density of bonding pads of the electronic unit will increase, so that the density of the bonding pads of the redistribution layer 36 (or the redistribution layer 16) needs to be increased. In the electronic device 1 of this embodiment, since the transparent core substrate 12 have higher stiffness than that of Bismaleimide-Triazine (BT) resin and that of the insulating layers of the redistribution layer 16 and the redistribution layer 36, the warpage generated during manufacturing the electronic device 1, during being disposed on other elements, or during other elements being disposed on the electronic device 1 may be reduced to improve product yield. In addition, since the aperture uniformity of one of the through holes TH of the transparent core substrate 12 may be improved through the above-mentioned method for manufacturing the electronic device 1, damage to the conductive vias 26 disposed in the through holes TH due to being subjected to external force may be reduced.

The electronic device and the manufacturing method thereof in the present disclosure are not limited to the above-mentioned embodiments, and may have different embodiments or variant embodiments. To simplify the description, the same reference numerals as those in the first embodiment are used to mark the same elements in different embodiments or variant embodiments of the present disclosure. To clearly describe different embodiments or variant embodiments, following content details the differences between different embodiments or variant embodiments, and repeated parts will not be redundantly detailed.

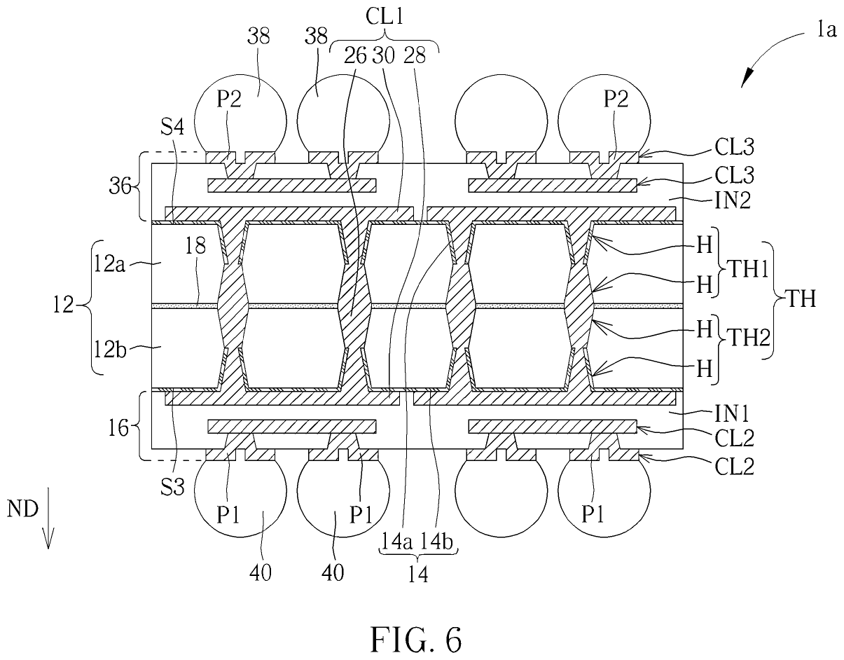

Refer to FIG. 6, which schematically illustrates a cross-sectional view of an electronic device according to a first variant embodiment of the first embodiment of the present disclosure. As shown in FIG. 6, the buffer layer 14 of the electronic device la provided in this variant embodiment may not cover the sidewalls of one of the through holes TH adjacent to the interposer 18. For example, the sidewalls of the hole H of the sub-through hole TH1 adjacent to the sub-through hole TH2 and the sidewalls of the hole H of the sub-through hole TH2 adjacent to the sub-through hole TH1 may not have the buffer layer 14 disposed thereon, so that the buffer layer 14 may include a portion 14a disposed on the transparent core layer 12a and a portion 14b disposed on the transparent core layer 12b, and the portion 14a and the portion 14b may be separated from each other. In some embodiments, the portion 14a and the portion 14b of the buffer layer 14 of FIG. 6 may be applied to any of the embodiments mentioned below. Other parts of the electronic device 1a and its manufacturing method may be the same as the embodiment of FIG. 1 to FIG. 5, so they are not described in detail herein.

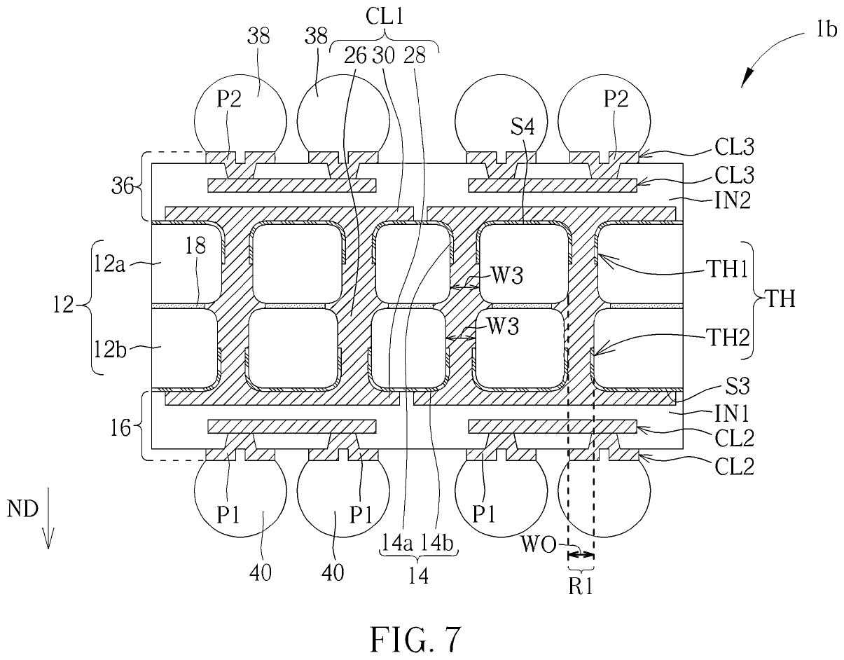

Refer to FIG. 7, which schematically illustrates a cross-sectional view of an electronic device according to a second variant embodiment of the first embodiment of the present disclosure. As shown in FIG. 7, one of the sub-through holes TH1 and one of the sub-through holes TH2 of the electronic device 1b provided in this variant embodiment may have substantially the same aperture W3. In other words, a sidewall of the sub-through hole TH1 and a sidewall of the sub-through hole TH2 may be parallel to the normal direction ND of the surface S3, so that the sub-through hole TH1 and the sub-through hole TH2 may be rectangular in a cross-sectional view. In some embodiments, the sub-through hole TH1 and the sub-through hole TH2 may have an overlapping area R1, and the overlapping area R1 includes an overlapping width WO, wherein the overlapping width WO is greater than or equal to 0.5 times the aperture W3 and less than or equal to the aperture W3 (i.e., 0.5 times the aperture W3≤the overlapping width WO≤the aperture W3). Other parts of the electronic device 1b and the manufacturing method thereof may be the same as the embodiment of FIG. 1 to FIG. 5 or the variant embodiment of FIG. 6, so they are not detailed herein. In addition, according to some embodiments, the transparent core substrate 12 may have an arc-shaped corner to reduce cracks or damage risk of a layer coated on the transparent core substrate 12, but not limited thereto. In some embodiments, the range of the overlapping width WO of the overlap area R1 in FIG. 7 and/or the arc-shaped corner of the transparent core substrate 12 may be applied to any of the above or the following embodiments.

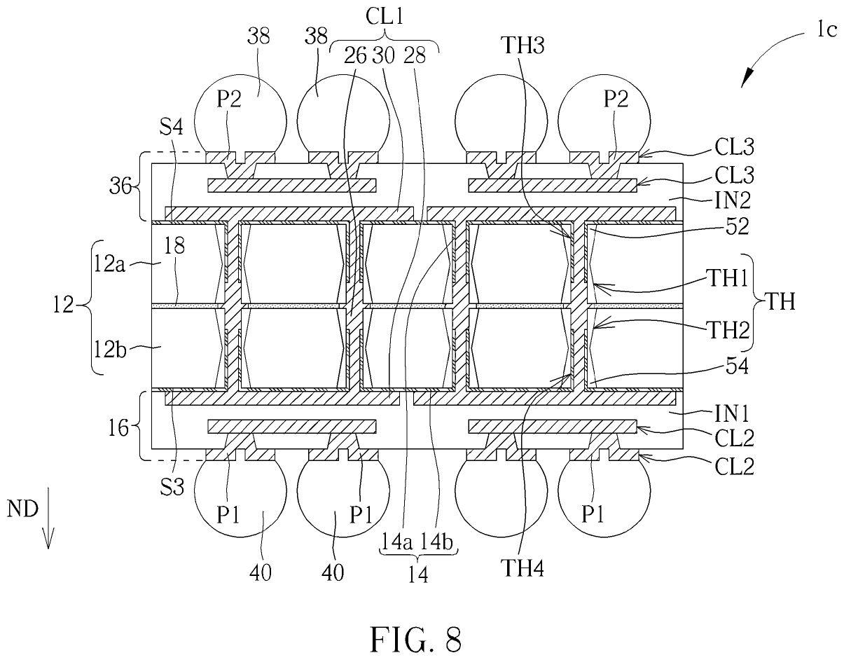

Refer to FIG. 8, which schematically illustrates a cross-sectional view of an electronic device according to a third variant embodiment of the first embodiment of the present disclosure. As shown in FIG. 8, the electronic device 1c provided in this variant embodiment may further include a polymer layer disposed in the through hole TH, wherein the polymer layer may be disposed between the buffer layer 14 and the transparent core substrate 12. In FIG. 8, the electronic device 1c may include a polymer layer 52 and a polymer layer 54 disposed on the sidewalls of the sub-through holes TH1 and the sidewalls of the sub-through holes TH2, respectively. The polymer layer 52 and the polymer layer 54 may respectively have a plurality of sub-through holes TH3 and a plurality of sub-through holes TH4 with substantially the same aperture, so as to uniformize the diameter of one of the conductive vias 26 formed in the corresponding sub-through hole TH1 and the corresponding sub-through hole TH2, thereby reducing cracks or damage to the conductive vias 26 when impacted. In some embodiments, the polymer layer of FIG. 8 may be applied to any of the above or below embodiments.

In some embodiments, the manufacturing method of the electronic device 1c may further include forming a polymer layer 52 in the sub-through hole TH1 between forming the transparent core layer 12a and bonding the transparent core layer 12b to the transparent core layer 12a, and forming the sub-through holes TH3 in the polymer layer 52 through a drilling process. Similarly, the sub-through holes TH4 of the polymer 54 may be formed by the same method as the formation of the sub-through holes TH3 between forming the transparent core layer 12b and bonding the transparent core layer 12b to the transparent core layer 12a, which will not be described in detail herein. Other parts of the electronic device 1c and other steps of the manufacturing method thereof may be the same as the embodiment of FIG. 1 to FIG. 5 or the variant embodiment of FIG. 6 or FIG. 7, so they are not repeated herein.

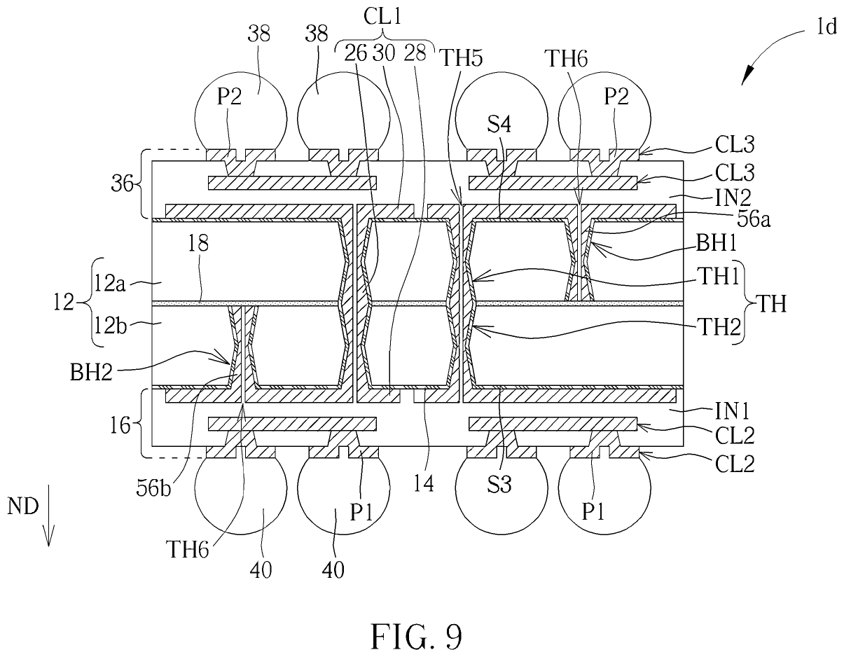

Refer to FIG. 9, which schematically illustrates a cross-sectional view of an electronic device according to a fourth variant embodiment of the first embodiment of the present disclosure. As shown in FIG. 9, the transparent core substrate 12 of the electronic device 1d provided in this variant embodiment may further include at least one blind hole disposed in the transparent core layer 12a or the transparent core layer 12b to reduce the unevenness of the stress in the electronic device 1d, thereby reducing the warpage of the electronic device 1d. In FIG. 9, the transparent core substrate 12 may include at least one blind hole BH1 and at least one blind hole BH2. In other words, the blind hole BH1 may be, for example, a sub-through hole of the transparent core layer 12a, and the blind hole BH1 does not overlap the sub-through holes of the transparent core layer 12b in a top view. Similarly, the blind hole BH2 may be a sub-through hole TH2 of the transparent core layer 12b, and the blind hole BH2 does not overlap the sub-through hole TH1 of the transparent core layer 12a in the top view. In this case, the electronic device le may further include a conductive material 56a and a conductive material 56b disposed in the blind hole BH1 and the blind hole BH2, respectively. The term “top view” herein may, for example, be referred to as the electronic device viewed along the normal direction ND perpendicular to the surface S3 of the transparent core substrate 12. In some embodiments, the conductive material 56a and the conductive material 56b may be formed of the conductive layer CL1, but not limited thereto. It is noted that since the blind hole BH1 is provided in the transparent core layer 12a and is not provided in the transparent core layer 12b, when a portion of the redistribution layer 16 corresponding to the blind hole BH1 generates larger tensile stress than a portion of the redistribution layer 36 corresponding to the blind hole BH1, the stress between the redistribution layer 16 and the redistribution layer 36 may be mitigated by providing the blind hole BH1 and the conductive material 56a in the blind hole BH1. Similarly, the blind hole BH2 with the conductive material 56b may also mitigate uneven stress between the redistribution layer 16 and the redistribution layer 36. In some embodiments, the blind hole BH1 and blind hole BH2 of FIG. 9 may be applied to any of the embodiments described above or below. In some of the embodiments, the blind hole BH1 and the blind hole BH2 are redundant connection design.

In some embodiments, the conductive vias 26 and the buffer layer 14 may not fill up the through hole TH. In other words, each of the conductive vias 26 may optionally have a through hole TH5 to mitigate the stress generated by the corresponding conductive via 26. In this case, each of the conductive material 56a and the conductive material 56b may have a through hole TH6, but not limited thereto. Other parts of the electronic device 1d and its manufacturing method may be the same as the embodiment of FIG. 1 to FIG. 5 or any of the variant embodiments of FIG. 6 to FIG. 8, so they are not described in detail herein. In some embodiments, the through holes TH5 and the through holes TH6 of FIG. 9 may be applied to any of the above or below embodiments.

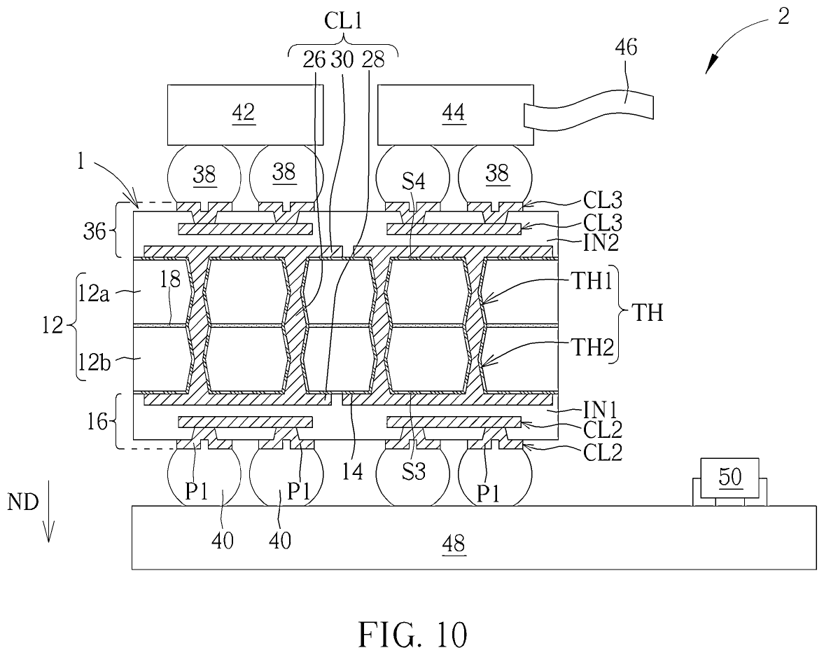

Refer to FIG. 10, which schematically illustrates a cross-sectional view of an electronic device according to a second embodiment of the present disclosure. As shown in FIG. 10, the electronic device 2 provided in this embodiment is a device structure using the electronic device 1. In the manufacturing method of the electronic device 2 provided in this embodiment, after forming the bonding pads 38 and the bonding pads 40, at least one electronic unit may be disposed on the electronic device 1. For example, an electronic unit 42 and an electronic unit 44 are disposed, so that the electronic unit 42 and the electronic unit 44 may be bonded to the redistribution layer 36 through the bonding pads 38. The functions of the electronic unit 42 and the electronic unit 44 may be adjusted according to requirements. The electronic unit 42 and/or the electronic unit 44 may include a chip, a chip package structure, a chip assembly structure or other types of component structures. The chip may have an active surface and a back surface, wherein a surface of the chip having the bonding pad may be, for example, the active surface for being bonded to the bonding pad 38. For example, the electronic unit 42 may be a control chip, and the electronic unit 44 may be a photonic integrated circuit. The electronic unit 44 may include, for example, an assembly structure of a photoelectric conversion element, an optical waveguide, a signal processing element, a micro-electromechanical element, and/or other suitable elements. In this case, the electronic device 2 may optionally further include an optical fiber 46 assembled on the electronic unit 44, such that the electronic unit 44 may receive optical signals through the optical fiber 46.

In some embodiments, after disposing the electronic unit 42 and the electronic unit 44, a side of the electronic device 1 away from the electronic unit 42 may be bonded to a circuit board 48 through the bonding pads 40, thereby forming the electronic device 2. In some embodiments, a passive component 50 may be optionally disposed on the circuit board 48. The passive component 50 may include, for example, a resistor, a capacitor, an inductor, or other suitable elements. In some embodiments, the electronic device 1 in FIG. 10 may be replaced with any one of the electronic devices in FIG. 6 to FIG. 9 and any of the electronic devices mentioned in the following embodiments, but not limited thereto.

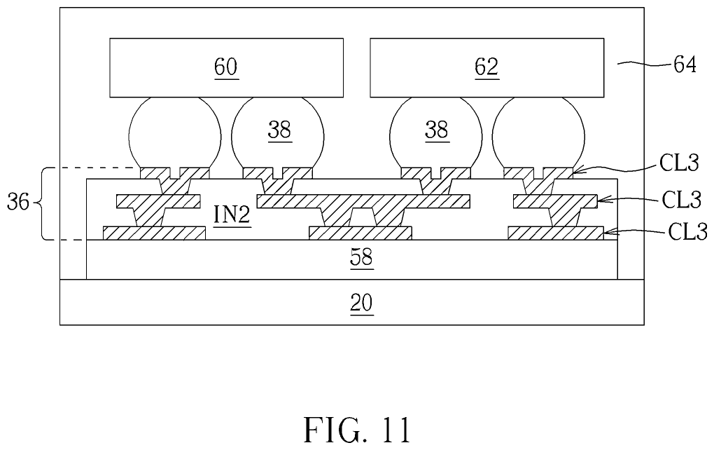

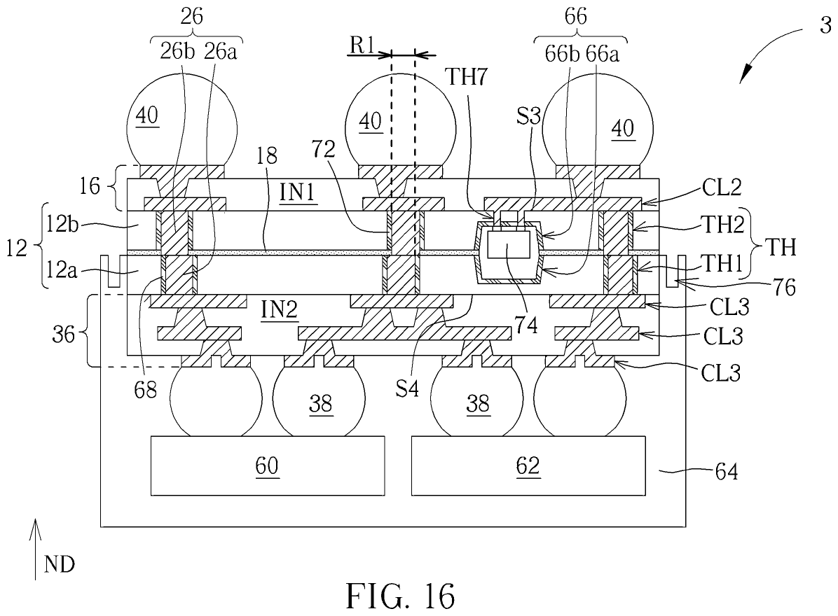

Refer to FIG. 11 to FIG. 16, which schematically illustrate cross-sectional views at different steps of a manufacturing method of an electronic device according to a third embodiment of the present disclosure, wherein FIG. 16 is a schematic cross-sectional view of the electronic device according to the third embodiment of the present disclosure. As shown in FIG. 11 to FIG. 16, a main difference between the manufacturing method of the electronic device 3 provided in this embodiment and the manufacturing method of FIG. 1 to FIG. 5 is that the step of forming the redistribution layer 16 of this embodiment is performed before forming the transparent core substrate 12 and the buffer layer 14. The manufacturing method of the electronic device 3 of this embodiment is further described in detail as follows. As shown in FIG. 11, first, the carrier 20 is provided, and a transparent substrate 58 is disposed on the carrier 20. In some embodiments, a release layer may be optionally formed on the carrier 20, but not limited thereto. Then, the redistribution layer 36 is formed on the transparent substrate 58, and the bonding pads 38 are formed on the redistribution layer 36. The step of forming the redistribution layer 36 may include forming at least one insulating layer and at least one conductive layer. The difference between the redistribution layer 36 of this embodiment and the above-mentioned embodiment is that the conductive layer may include a plurality of conductive layers CL3, but does not include the conductive layer CL1, but not limited thereto. Since other parts of the redistribution layer 36 and the methods of forming the insulating layer and forming the conductive layer are the same as those in the above embodiments, refer to the above content for them, and they are not redundantly detailed herein. In some embodiments, the layout structure of the redistribution layer 36 may be adjusted according to requirements.

As shown in FIG. 11, after forming the redistribution layer 36, an electronic unit 60 and an electronic unit 62 may be disposed on the redistribution layer 36, wherein the electronic unit 60 and the electronic unit 62 may be bonded to the redistribution layer 36 through the bonding pads 38. Subsequently, a protecting layer 64 is formed on the redistribution layer 36. The protecting layer 64 may, for example, include an encapsulating material. For example, the step of forming the protecting layer 64 may include performing a molding process. The protecting layer 64 may be formed on the carrier 20, the redistribution layer 36, the electronic unit 60, and the electronic unit 62, and may extend over the sidewalls of the redistribution layer 36 and the carrier 20, but not limited thereto. The protecting layer 64 may surround at least the electronic unit 60 and the electronic unit 62. In the present disclosure, an element “surrounding” another element may refer to the element at least contacting a side surface of the another element in a cross-sectional view. For example, the protecting layer 64 may at least contact a side surface of the electronic unit 60 and a side surface of the electronic unit 62. In some embodiments, the protecting layer 64 on back surfaces of the electronic unit 60 and the electronic unit 62 away from the redistribution layer 36 may optionally be further removed by a thinning process, but not limited thereto. In some embodiments, the protecting layer 64 may not extend to a sidewall of the carrier 20.

The functions of the electronic unit 60 and the electronic unit 62 may be adjusted according to the requirements. The electronic unit 60 and/or the electronic unit 62 may include, for example, a chip, a chip package structure, a chip assembly structure or other types of element structures. For example, the electronic unit may include a chip assembly structure of a stacked RAM and/or DRAM, but not limited thereto. In some embodiments, the electronic unit 60 and the electronic unit 62 may adopt the electronic unit 42 and/or the electronic unit 44 of FIG. 10, but not limited thereto.

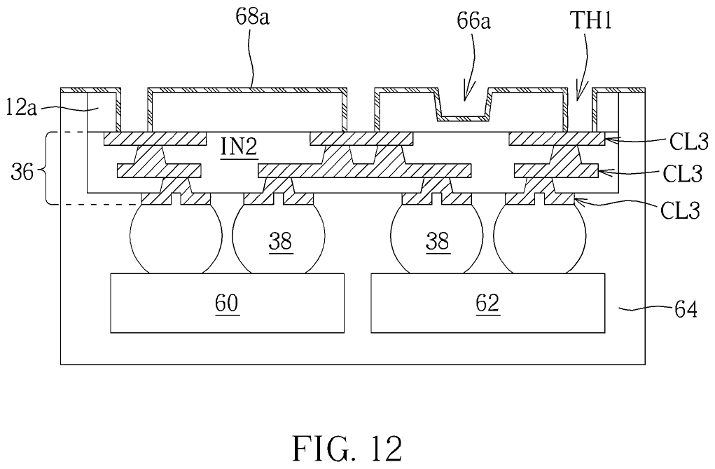

After forming the protecting layer 64, the step of forming the transparent core substrate 12 and the buffer layer 14 may be performed, as described below. As shown in FIG. 12, after forming the protecting layer 64, the carrier 20 is removed, and the transparent substrate 58 is turned upside down, so that the surface of the transparent substrate 58 away from the redistribution layer 36 faces upward. Then, a patterning process is performed on the transparent substrate 58 to form the transparent core layer 12a having the sub-through holes TH1, wherein the sub-through holes TH1 may expose a part of traces of the redistribution layer 36. The patterning process may be, for example, the same as the above-mentioned embodiment, and therefore will not be repeated here.

Then, a buffer material 68a is formed on the surface of the transparent core layer 12a away from the redistribution layer 36, in the sub-through hole TH1 of the transparent core layer 12a, and on the exposed traces of the redistribution layer 36. After that, the buffer material 68a located on a part of the traces of the redistribution layer 36 is removed to expose the traces of the redistribution layer 36.

In some embodiments, the step of forming the transparent core layer 12a may optionally further include forming a groove 66a on the surface of the transparent core layer 12a away from the redistribution layer 36, wherein the groove 66a does not penetrate the transparent core layer 12a. In this case, the step of forming the buffer material 68a may further form the buffer material 68a on sidewalls and bottom of the groove 66a. The buffer material 68a may, for example, include the same or similar material as the buffer layer 14 of the above-mentioned embodiment and may have the same or similar thickness as the buffer layer 14 of the above-mentioned embodiment, so it is not repeated here.

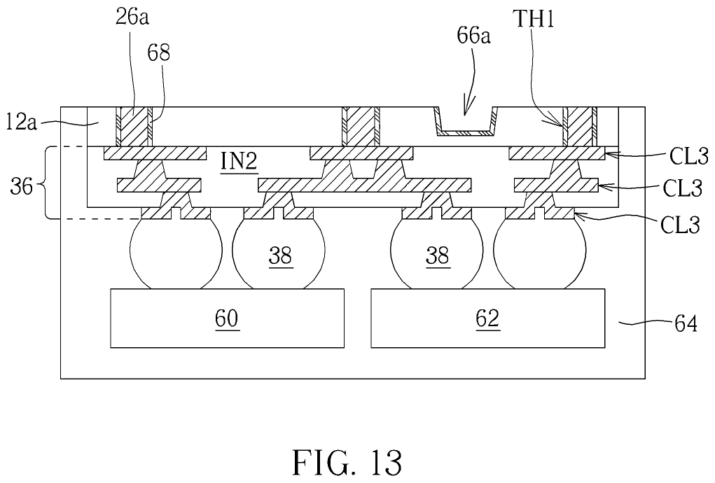

As shown in FIG. 13, a plurality of sub-conductive vias 26a may be then formed in the sub-through holes TH1, respectively, and the buffer material 68a located outside the sub-through holes TH1 and the groove 66a may be removed to form a buffer layer 68 in the sub-through holes TH1. Since the step of forming the redistribution layer 36 is performed before forming the transparent core substrate 12, the conductive layer of the redistribution layer 36 may be different from the conductive layer for forming the sub-conductive vias 26a. The step of forming the sub-conductive vias 26a may, for example, include a metallization process, wherein the metallization process may, for example, include evaporation, sputtering, electroplating, electroless plating, deposition or other suitable processes. The sub-conductive vias 26a may include a conductive material, such as tantalum, titanium, ruthenium, tungsten, copper or other suitable materials. It should be noted that since the buffer material 68a is disposed on the surface of the transparent core layer 12a outside the sub-through holes TH1 during the metallization process, the influence of the conductive material formed on the surface of the transparent core layer 12a on the transparent core layer 12a may be reduced.

In some embodiments, when the groove 66a is formed on the surface of the transparent core layer 12a, the buffer layer 68 is also formed in the groove 66a. It should be noted that in the step of forming the sub-conductive vias 26a, the groove 66a may be shielded by a photoresist layer, so that the buffer material 68a in the groove 66a is not removed to form the buffer layer 68, and no conductive material is disposed in the groove 66a. In one embodiment, the sub-through holes TH1 may be filled up with or not filled up with the sub-conductive vias 26b, respectively.

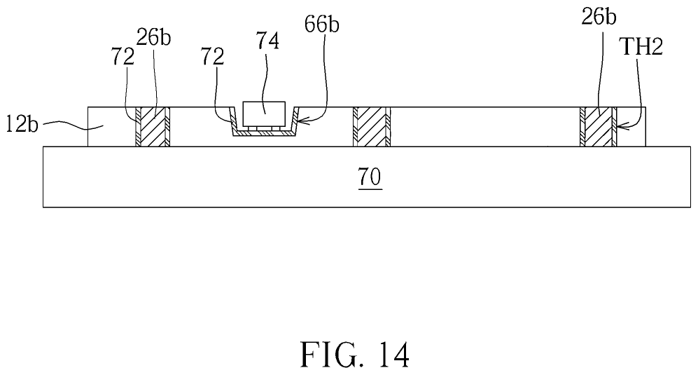

As shown in FIG. 14, another transparent substrate may be provided on another carrier 70, and the transparent substrate may be patterned to form the transparent core layer 12b having the sub-through holes TH2. Then, another plurality of sub-conductive vias 26b and another buffer layer 72 are formed in the sub-through holes TH2, wherein the buffer layer 72 is disposed between the sidewall of the sub-through hole TH2 and the sub-conductive vias 26b. The method of forming the buffer layer 72 may be the same as the method of forming the buffer layer 68, and the method of forming the sub-conductive vias 26b may be the same as the method of forming the sub-conductive vias 26a, so they are not redundantly detailed herein. In one embodiment, the sub-through holes TH2 may or may not be filled up with the sub-conductive vias 26b. In some embodiments, a release layer may be optionally formed on the carrier 70, but not limited thereto.

In some embodiments, when a groove 66a is formed in the transparent core layer 12a, the step of forming the transparent core layer 12b may further include forming another groove 66b on the surface of the transparent core layer 12b away from the carrier 70, wherein the groove 66b does not penetrate the transparent core layer 12b. In this case, the step of forming the buffer layer 72 may further form the buffer layer 72 in the sidewall and bottom of the groove 66a. After forming the sub-conductive vias 26b, an electronic unit 74 may be optionally disposed in the groove 66b. It should be noted that the steps of forming the transparent core layer 12b, the buffer layer 72, the sub-conductive via 26b, and the groove 66b and disposing the electronic unit 74 do not affect the steps shown in FIG. 13, so the steps of forming the transparent core layer 12b, the buffer layer 72, the sub-conductive vias 26b and the groove 66b and disposing the electronic unit 74 may be performed before or after the steps of FIG. 13 or simultaneously with the steps of FIG. 13.

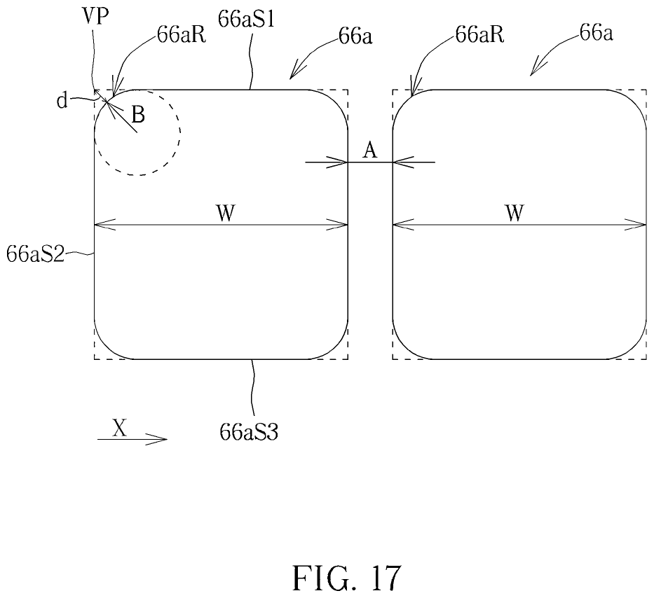

According to design requirements, shapes of top view outlines of the groove 66a and the groove 66b may be rectangles, polygons or other suitable shapes, and a shape of a top view outline of the through hole TH may be a circle, an ellipse, a rectangle, a polygon or other suitable shapes. Refer to FIG. 17, which schematically illustrates a top view of the grooves according to some embodiments of the present disclosure. FIG. 17 takes the groove 66a as an example, but not limited to this. The top view outline of the groove 66b may be similar to or the same as the groove 66a and will not be described in detail herein. For example, the top view outline of the groove 66a or the groove 66b includes adjacent straight edges 66aS1 and 66aS2 that are not parallel to each other, wherein the top view outline of the groove 66a or the groove 66b further includes another straight edge 66aS3 substantially parallel to the straight edge 66aS1, and adjacent two of these straight edges of the top view outline are connected, for example, through an arc edge 66aR, but not limited thereto. In some embodiments, radius of curvature B of the arc edge 66aR may range from 0.01 mm to 5 mm. In some embodiments, as shown in FIG. 17, an extension line of the straight edge 66aS1 and an extension line of the straight edge 66aS2 of the top view outline of the groove 66a may intersect at a virtual point VP, and the virtual point VP is spaced apart from the arc edge 66aR by a shortest distance d. The groove 66a may have a maximum width W in a direction X, and a ratio of the shortest distance d to the maximum width W conforms to the following relationship:

0<d/W≤0.1 (e.g., 0<d/W≤0.06),

when the shortest distance d is smaller, the arc edge 66aR of the groove 66a may be closer to a right angle. According to some embodiments, the electronic device may include a plurality of grooves 66a, and there may be a distance A between two adjacent grooves 66a, wherein a ratio of the distance A to the radius of curvature B (distance A/radius of curvature B) may be greater than 0.5, or greater than 0.7. The above configuration may reduce the risk of cracking caused by too small pitch between the grooves 66a, but not limited thereto. According to some embodiments, the groove 66b may have the same as or similar structure as the groove 66a, as shown in FIG. 17, but not limited thereto.

In some embodiments, the electronic unit 74 may be disposed in the groove 66a. In this case, the step of forming the redistribution layer 36 may include forming lines used to be electrically connected to the electronic unit 74, and after forming the groove 66a, through holes may be further formed in the transparent core layer 12a at the bottom of the groove 66a. Furthermore, the step of forming the sub-conductive vias 26a may further include forming a plurality of conductive vias in the through holes to electrically connect the electronic unit 74 to the redistribution layer 36, but the present disclosure is not limited to this.

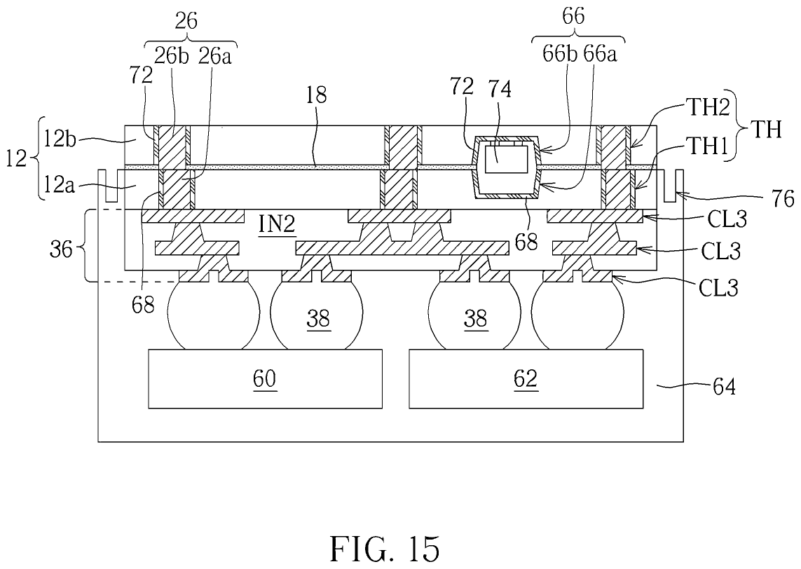

As shown in FIG. 15, after forming the sub-conductive via 26a and the sub-conductive via 26b (or after disposing the electronic unit 74), the transparent core layer 12b may be turned upside down, and the transparent core layer 12b may be bonded to the surface of the transparent core layer 12a away from the redistribution layer 36 through the interposer 18 to form the transparent core substrate 12. In addition, one of the sub-through holes TH2 may overlap the corresponding sub-through hole TH1 in the top view to form the through hole TH, and one of the sub-conductive vias 26b may overlap the corresponding sub-conductive via 26a in the top view to form the conductive via 26.

In some embodiments, before bonding the transparent core layer 12b to the transparent core layer 12a, an alignment mark 76 may be formed on the surface of the protecting layer 64 adjacent to the transparent core layer 12a to facilitate alignment of the sub-through holes TH2 of the transparent core layer 12b with the sub-through holes TH1 of the transparent core layer 12a. The alignment mark 76 may be, for example, a groove of the protecting layer 64 or other suitable mark.

In some embodiments, when a groove 66a is formed in the transparent core layer 12a, and a groove 66b is formed in the transparent core layer 12b, the step of bonding the transparent core layer 12b to the transparent core layer 12a may further include disposing the groove 66b with the electronic unit 74 on the groove 66a, wherein the groove 66b may correspond to the groove 66a in a top view to form an accommodating space 66 for accommodating the electronic unit 74 disposed in the groove 66b. For example, a height of the electronic unit 74 may be greater than a depth of the groove 66b and a depth of the groove 66a, and less than a sum of the depth of the groove 66b and the depth of the groove 66a, so that collision of the electronic unit 74 may be avoided during the lamination process of stacking the transparent core layer 12b and the transparent core layer 12a.

As shown in FIG. 16, after the transparent core substrate 12 is formed, the redistribution layer 16 may be formed on the surface S3 of the transparent core substrate 12 away from the redistribution layer 36, and then the bonding pads 40 may be formed on the redistribution layer 16, thereby forming the electronic device 3. Since the step of forming the redistribution layer 16 is performed after forming the sub-conductive vias 26b, the conductive layer CL2 of the redistribution layer 16 may be different from the conductive layer used for forming the sub-conductive vias 26b. In some embodiments, before the step of forming the redistribution layer 16, through holes TH7 may be formed in parts of the transparent core layer 12b located at the bottom of the groove 66b, so that the conductive layer CL2 of the redistribution layer 16 may extend into the through holes TH7 to be electrically connected to the electronic unit 74.

As shown in FIG. 16, in the electronic device 3 of the present embodiment, the buffer layer 68 and the buffer layer 72 may be respectively disposed in the sub-through holes TH1 and the sub-through holes TH2, and may not extend outside the through holes TH, but not limited thereto. In addition, it is noted that when the transparent core layer 12a has a groove 66a, and the transparent core layer 12b has a groove 66b facing the groove 66a, the electronic unit 74 may be disposed in the groove 66a and the groove 66b, thereby reducing the signal transmitting distance between the electronic unit 74 and the electronic unit 60 and/or between the electronic unit 74 and the electronic unit 62 and improving the computing performance of the electronic device 3. The function of the electronic unit 74 may be adjusted according to requirements. The electronic unit 74 may, for example, include a chip, which may, for example, include an active element and/or a passive element. In some embodiments, the electronic device 3 of FIG. 16 may not include the groove 66a, the groove 66b and the electronic unit 74. Other parts of the electronic device 3 and its manufacturing method may adopt any one of the embodiments of FIG. 1 to FIG. 10, so they are not redundantly detailed herein.

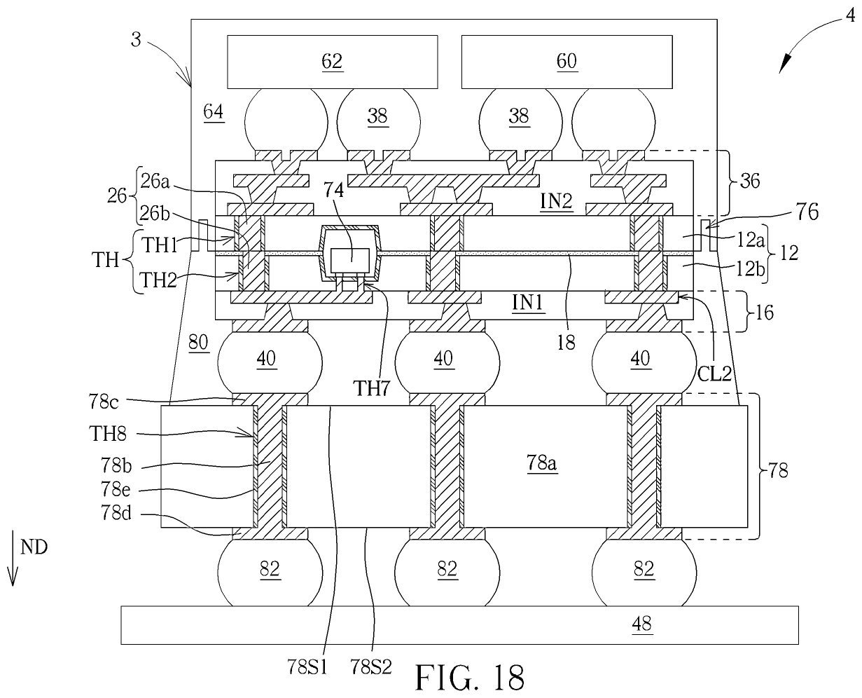

Refer to FIG. 18, which schematically illustrates a cross-sectional view of an electronic device according to a fourth embodiment of the present disclosure. As shown in FIG. 18, the manufacturing method of the electronic device 4 provided in this embodiment may include bonding the electronic device 3 to a circuit carrier 78 through the bonding pads 40 after forming the electronic device 3. In some embodiments, the circuit carrier 78 may include a core substrate 78a and a plurality of conductive vias 78b, wherein the core substrate 78a may have a plurality of through holes TH8, and the conductive vias 78b may be respectively disposed in the corresponding through holes TH8 and penetrate through the core substrate 78a. The circuit carrier 78 may further include a plurality of bonding pads 78c and a plurality of bonding pads 78d respectively disposed on an upper surface 78S1 and a lower surface 78S2 of the core substrate 78a. In some embodiments, the circuit carrier 78 of FIG. 18 may adopt the transparent core substrate 12 formed with the conductive layer CL1 as shown in FIG. 3. Alternatively, the core substrate 78a of FIG. 18 may include BT resin or other suitable core substrate materials. In some embodiments, the circuit carrier 78 may further include another buffer layer 78e disposed in the through hole TH8 and between the conductive vias 78b and the core substrate 78a, but not limited thereto. In some embodiments, the circuit carrier 78 of FIG. 18 may be replaced with any one of the electronic devices of FIG. 5 to FIG. 9.

In some embodiments, after the electronic device 3 is bonded to the circuit carrier 78, an adhesive layer 80 may be provided between the electronic device 3 and the circuit carrier 78 to improve adhesion between the electronic device 3 and the circuit carrier 78. In some embodiments, the circuit carrier 78 may further be bonded to the circuit board 48 through bonding pads 82. The adhesive layer 80 may, for example, include an underfill adhesive or other suitable materials.

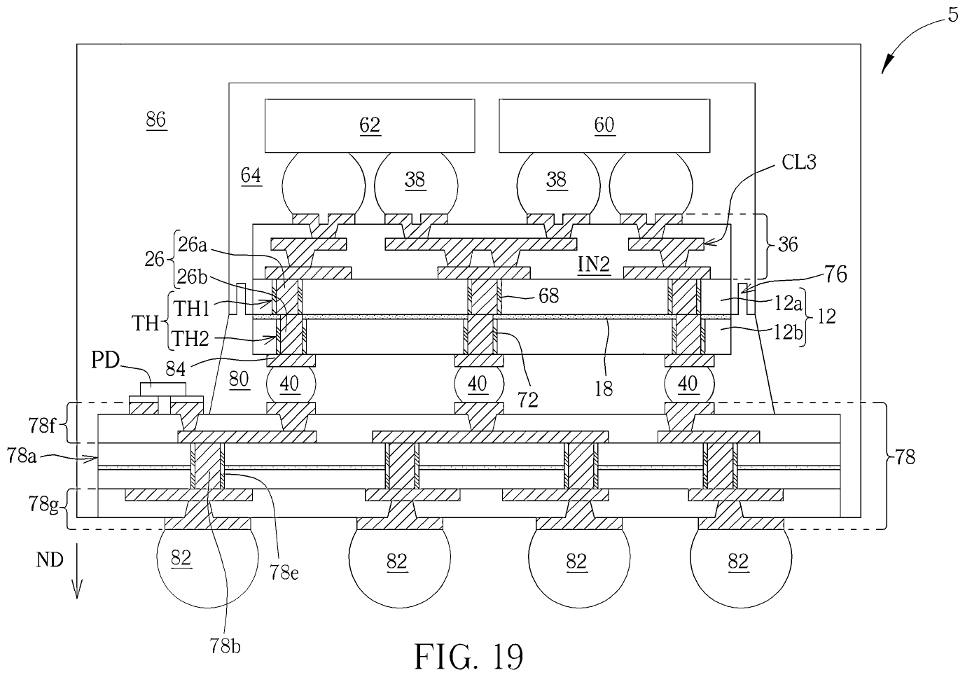

Refer to FIG. 19, which schematically illustrates a cross-sectional view of an electronic device according to a fifth embodiment of the present disclosure. As shown in FIG. 19, a main difference between the electronic device 5 of this embodiment and the electronic device 4 of FIG. 18 is that the electronic device 5 may not include the redistribution layer 16, and a side of the transparent core substrate 12 away from the redistribution layer 36 may be bonded to the circuit carrier 78. Specifically, the electronic device 5 may include a plurality of bonding pads 84 disposed on the side of the transparent core substrate 2 away from the redistribution layer 36 and electrically connected to the corresponding conductive via 26, so that the conductive via 26 may be bonded and electrically connected to the circuit carrier 78 through the bonding pads 40. In some embodiments, the bonding pads 84 may be optionally replaced with the redistribution layer 16 of FIG. 18.

In the embodiment of FIG. 19, the circuit carrier 78 may further include a redistribution layer 78f and a redistribution layer 78g disposed on an upper side and a lower side of the core substrate 78a, respectively. The redistribution layer 78f may be used to be bonded to and electrically connected to the bonding pads 84. The redistribution layer 78g may be used to be bonded to other elements. In some embodiments, the circuit carrier 78 of FIG. 19 may adopt any one of the electronic devices of FIG. 5 to FIG. 9. Other elements may include a circuit board or other electronic elements, but not limited thereto. According to some embodiments, circuit carrier 78 may not include the redistribution layer.

In some embodiments, the electronic device 5 may further include a protecting layer 86 and at least one electronic element PD. The protecting layer 86 is disposed on the protecting layer 64, the adhesive layer 80 and the circuit carrier 78 to protect the electronic unit 60, the electronic unit 62, the transparent core substrate 12 and the circuit carrier 78. The protecting layer 86 may, for example, include a packaging material, but not limited thereto. The electronic element PD may include a resistor, a capacitor, an inductor, other surface elements, or any combination of the above. The electronic element PD may be bonded to the circuit carrier 78 through bonding pads. Specifically, the electronic element PD may be bonded to the redistribution layer 78f through bonding pads. According to some embodiments, the electronic element PD may not overlap the electronic unit 60 or the electronic unit 62. According to some embodiments, the electronic element PD may optionally overlap at least one of the electronic unit 60 or the electronic unit 62. Other parts of the electronic device 5 and its manufacturing method may adopt any one of the embodiments of FIG. 1 to FIG. 18, so they are not redundantly described herein.

In summary, in the electronic device and the manufacturing method thereof of the present disclosure, stacking plural transparent core layers may improve the stiffness of the transparent core substrate and reduce the difference between the maximum aperture and the minimum aperture of the through hole. Therefore, the transparent core substrate may be used as a core substrate to mitigate the warpage during forming the redistribution layer, thereby improving the yield of manufacturing the electronic device. In addition, since the difference between the maximum aperture and the minimum aperture of the through hole is reduced, the difference between the maximum diameter and the minimum diameter of the conductive via formed in the through hole is also decreased, thereby reducing cracks or disconnections of the conductive via caused by stress or external force on the conductive via.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a transparent core substrate comprising a through hole, wherein the transparent core substrate comprises:
a first transparent core layer comprising a first sub-through hole; and
a second transparent core layer bonded to the first transparent core layer, wherein the second transparent core layer comprises a second sub-through hole, and the first sub-through hole overlaps the second sub-through hole to form the through hole; and
a first buffer layer disposed in at least a part of the through hole.

2. The electronic device as claimed in claim 1, wherein the first sub-through hole has an aperture, the first sub-through hole and the second sub-through hole have an overlapping area, the overlapping area comprises an overlapping width, and the overlapping width is greater than or equal to 0.5 times the aperture and less than or equal to the aperture.

3. The electronic device as claimed in claim 1, further comprising an interposer disposed between the first transparent core layer and the second transparent core layer, wherein a thickness of the interposer is greater than or equal to 1 nanometer and less than or equal to 20 nanometers.

4. The electronic device as claimed in claim 3, wherein the interposer has a dissipation factor, and the dissipation factor is greater than or equal to 0.001 and less than or equal to 0.01 at an operating frequency greater than or equal to 10 MHz.

5. The electronic device as claimed in claim 3, wherein a refractive index of the interposer is different from a refractive index of the first transparent core layer.

6. The electronic device as claimed in claim 1, further comprising an interposer disposed between the first transparent core layer and the second transparent core layer, wherein the interposer includes a material different from a material of the first transparent core layer.

7. The electronic device as claimed in claim 1, further comprising a conductive via, a first redistribution layer, a second redistribution layer, the conductive via being disposed in the through hole, wherein the transparent core substrate is disposed between the first redistribution layer and the second redistribution layer, and the first redistribution layer is electrically connected to the second redistribution layer through the conductive via.

8. The electronic device as claimed in claim 1, wherein the first buffer layer is disposed in the first sub-through hole, and the electronic device further comprises a second buffer layer disposed in the second sub-through hole.

9. The electronic device as claimed in claim 1, wherein the first transparent core layer has a first groove, the second transparent core layer has a second groove facing the first groove, wherein the electronic device further comprises an electronic unit disposed in the first groove and the second groove.

10. The electronic device as claimed in claim 1, further comprising a polymer layer disposed in the through hole, wherein the polymer layer is disposed between the first buffer layer and the transparent core substrate.

11. The electronic device as claimed in claim 1, wherein each of the first transparent core layer and the second transparent core layer comprises a glass substrate.

12. The electronic device as claimed in claim 1, wherein in a cross-sectional view of the electronic device, the first sub-through hole has hourglass shape.

13. A manufacturing method of an electronic device, comprising:
forming a transparent core substrate and a first buffer layer, wherein the transparent core substrate comprises a through hole, the first buffer layer is disposed in at least a part of the through hole, and the transparent core substrate comprises:
a first transparent core layer comprising a first sub-through hole; and
a second transparent core layer bonded to the first transparent core layer, wherein the second transparent core layer comprises a second sub-through hole, and the first sub-through hole overlaps the second sub-through hole to form the through hole; and
forming a first redistribution layer on a surface of the first transparent core layer away from the second transparent core layer.

14. The manufacturing method of the electronic device as claimed in claim 13, wherein the first redistribution layer is formed after forming the transparent core substrate and the first buffer layer, and the manufacturing method further comprises forming a conductive via in the through hole between forming the transparent core substrate and the first buffer layer and forming the first redistribution layer.

15. The manufacturing method of the electronic device as claimed in claim 14, wherein forming the transparent core substrate comprises:
forming the first transparent core layer and the second transparent core layer separately; and
bonding the second transparent core layer to the first transparent core layer through an interposer.

16. The manufacturing method of the electronic device as claimed in claim 14, further comprising forming a second redistribution layer on a surface of the second transparent core layer away from the first transparent core layer after forming the first redistribution layer.

17. The manufacturing method of the electronic device as claimed in claim 13, wherein the first redistribution layer is formed before forming the transparent core substrate and the first buffer layer, and the manufacturing method further comprises disposing at least one electronic unit on the first redistribution layer and forming a protecting layer on the first redistribution layer between forming the first redistribution layer and forming the transparent core substrate and the first buffer layer.

18. The manufacturing method of the electronic device as claimed in claim 17, wherein forming the transparent core substrate comprises:
forming the first transparent core layer comprising the first sub-through hole after forming the first redistribution layer;
forming a first sub-conductive via and the first buffer layer in the first sub-through hole;
forming the second transparent core layer comprising the second sub-through hole;
forming a second sub-conductive via and a second buffer layer in the second sub-through hole; and
bonding the second transparent core layer to the first transparent core layer through an interposer, wherein the second sub-conductive via overlaps the first sub-conductive via to form a conductive via.

19. The manufacturing method of the electronic device as claimed in claim 18, wherein forming the first transparent core layer comprises forming a first groove on a surface of the first transparent core layer away from the first redistribution layer, and forming the second transparent core layer comprises forming a second groove on a surface of the second transparent core layer, wherein the manufacturing method further comprises disposing another electronic unit in the second groove, and bonding the second transparent core layer to the first transparent core layer comprises disposing the second groove on the first groove.

20. The manufacturing method of the electronic device as claimed in claim 17, further comprising forming a second redistribution layer on a surface of the transparent core substrate away from the first redistribution layer.
